(19) United States
(12) Patent Application Publication
(10) Pub. No.: US 2015/0137259 A1
(43) Pub. Date: May 21, 2015

(54) SEMICONDUCTOR DEVICE

(71) Applicants: Hauk HAN, Hwaseong-si (KR); Yu Min KIM, Yongin-si (KR); Ki Hyun YOON, Hwaseong-si (KR); Myoung Bum LEE, Seoul (KR); Chang Won LEE, Seongnam-si (KR); Joo Yeon HA, Seoul (KR)

(72) Inventors: Hauk HAN, Hwaseong-si (KR); Yu Min KIM, Yongin-si (KR); Ki Hyun YOON, Hwaseong-si (KR); Myoung Bum LEE, Seoul (KR); Chang Won LEE, Seongnam-si (KR); Joo Yeon HA, Seoul (KR)

(21) Appl. No.: 14/453,705

(22) Filed: Aug. 7, 2014

(30) Foreign Application Priority Data
Nov. 18, 2013 (KR) 10-2013-0140116

(51) Int. Cl. H01L 29/417; H01L 27/088; H01L 29/45

(52) U.S. Cl. CPC H01L 29/4175; H01L 29/45; H01L 27/088
USPC 257/384; 257/763; 257/773

(57) ABSTRACT

A semiconductor device includes a substrate including a conductive region, an insulating layer disposed on the substrate and including an opening exposing the conductive region, and a conductive layer buried within the opening and including a first region disposed on inner side walls of the opening and a second region disposed within the first region. The first region includes a plurality of first crystal grains and the second region includes a plurality of second crystal grains. The pluralities of first and second crystal grains are separated from each other at a boundary formed between the first and second regions.

### CROSS-REFERENCE TO RELATED APPLICATIONS

This application claims priority under 35 U.S.C. §119 to Korean Patent Application No. 10-2013-0140116 filed on Nov. 18, 2013, the disclosure of which is incorporated by reference herein in its entirety.

### TECHNICAL FIELD

Exemplary embodiments of the present inventive concept relate to a semiconductor device.

### DISCUSSION OF THE RELATED ART

As the size of semiconductor devices has been reduced, high capacity data processing requirements still exist. Thus, to achieve high capacity data processing in a semiconductor device having a reduced size, integration of semiconductor elements constituting semiconductor devices may be increased.

### SUMMARY

Exemplary embodiments of the present inventive concept may provide a semiconductor device free from defects and having improved reliability.

According to an exemplary embodiment, a semiconductor device may include a substrate including a conductive region, an insulating layer including an opening exposing the conductive region, and a conductive layer buried within the opening and including a first region disposed on inner side walls of the opening and a second region disposed within the first region. Crystal grains constituting each of the first and second regions may be disposed to be contiguous with each other in a boundary between the first and second regions.

The second region may be positioned at a predetermined depth within the opening from an upper surface of the insulating layer, and lateral and lower surfaces thereof may be surrounded by the first region.

The second region may have a width that gradually decreases from below a predetermined depth to have a lowermost point.

The first region may include a plurality of first crystal grains grown in one direction toward the center of the opening, and the second region may include a plurality of second crystal grains grown in the one direction from the boundary with the first region.

The plurality of first and second crystal grains may have a columnar structure grown in the one direction.

The plurality of second crystal grains may be in contact with each other so as to be disposed in two columns.

The conductive layer may have a first width in an upper surface of the conductive layer and a second width smaller than the first width in a lower surface thereof, and may include a bowing region positioned therebetween. The bowing region may have a third width greater than the first width.

The second region may extend at least up to the bowing region from the upper surface of the conductive layer.

The second region may have a width that increases up to the bowing region from the upper surface of the conductive layer and decreases in a lower portion of the bowing region.

The bowing region may be positioned at a height higher than a middle portion of the conductive layer.

An aspect ratio of the opening may range from about 1:10 to about 1:30.

The conductive layer may include tungsten (W) or aluminum (Al).

According to an exemplary embodiment, a semiconductor device may include a substrate including a conductive region, a plurality of channel regions extending in a direction perpendicular to an upper surface of the substrate, gate electrodes and interlayer insulating layers alternately stacked on the substrate along outer side walls of the plurality of channel regions, an insulating layer including an opening exposing the conductive region and disposed between a plurality of adjacent channel regions, and a common source layer buried within the opening and including a first region grown on a lateral surface of the insulating layer and a second region grown on a lateral surface of the first region such that the second region is disconnected from the first region.

The conductive region may include silicide.

The common source layer may have a line shape or a pillar shape.

According to an exemplary embodiment, a semiconductor device includes a substrate including a conductive region, an insulating layer disposed on the substrate and including an opening exposing the conductive region, and a conductive layer buried within the opening and including a first region disposed on inner side walls of the opening and a second region disposed within the first region. The first region includes a plurality of first crystal grains and the second region includes a plurality of second crystal grains. The pluralities of first and second crystal grains are separated from each other at a boundary formed between the first and second regions.

According to an exemplary embodiment, a semiconductor device includes a substrate including a conductive region, an insulating layer disposed on the substrate and including an opening exposing the conductive region, and a conductive layer buried within the opening and including a first region disposed on inner side walls of the opening and a second region disposed within the first region. The first and second regions are separated from each other at a boundary formed between the first and second regions. Lateral surfaces and lower surfaces of the second region are surrounded by the first region.

### BRIEF DESCRIPTION OF THE DRAWINGS

The above and other features of the present inventive concept will become more apparent by describing in detail exemplary embodiments thereof with reference to the accompanying drawings, in which:

FIG. 1 is a cross-sectional view schematically illustrating a semiconductor device according to an exemplary embodiment of the present inventive concept.

FIG. 2 is a partially enlarged view schematically illustrating a semiconductor device according to an exemplary embodiment of the present inventive concept.

FIG. 3 is a flowchart illustrating a method of manufacturing a semiconductor device according to an exemplary embodiment of the present inventive concept.

FIGS. 4A through 4F are cross-sectional views illustrating sequential processes of a method of manufacturing a semiconductor device according to an exemplary embodiment of the present inventive concept.

FIGS. 5A and 5B are electron microscope photographs illustrating a conductive layer that may be implemented in a semiconductor device according to an exemplary embodiment of the present inventive concept.

FIG. 6 is a perspective view schematically illustrating a semiconductor device according to an exemplary embodiment of the present inventive concept.

FIGS. 7A through 7F are cross-sectional views illustrating processes of a method of manufacturing a semiconductor device according to an exemplary embodiment of the present inventive concept.

FIG. 8 is a cross-sectional view illustrating a semiconductor device according to an exemplary embodiment of the present inventive concept.

FIG. 9 is a block diagram illustrating a storage device including a semiconductor device according to an exemplary embodiment of the present inventive concept.

FIG. 10 is a block diagram illustrating an electronic device including a semiconductor device according to an exemplary embodiment of the present inventive concept.

FIG. 11 is a view schematically illustrating an electronic system including a semiconductor device according to an exemplary embodiment of the present inventive concept.

### DETAILED DESCRIPTION OF THE EXEMPLARY EMBODIMENTS

Exemplary embodiments of the present inventive concept will be described more fully hereinafter with reference to the accompanying drawings. Like reference numerals may refer to like elements throughout the accompanying drawings.

In the drawings, the shapes and dimensions of elements may be exaggerated for clarity.

Spatially relative terms, such as “upper”, “lower”, “lateral”, etc., may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. In addition, it will also be understood that when a layer is referred to as being “between” two layers, it can be the only layer between the two layers, or one or more intervening layers may also be present.

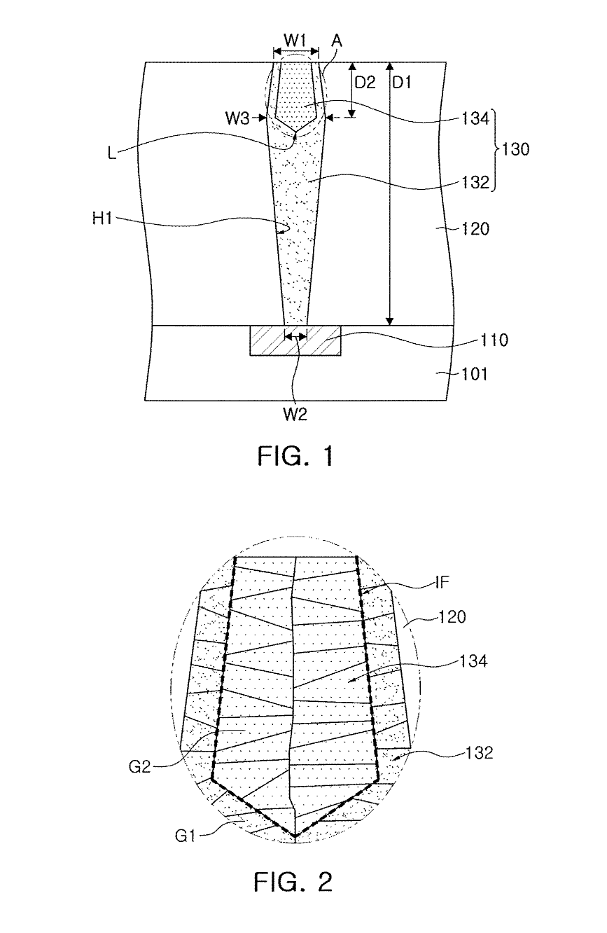

FIG. 1 is a cross-sectional view schematically illustrating a semiconductor device according to an exemplary embodiment of the present inventive concept.

Referring to FIG. 1, the semiconductor device may include a substrate 101, an insulating layer 120, and a conductive layer 130. The conductive layer 130 may be disposed within the insulating layer 120. The conductive layer 130 may include first and second regions 132 and 134. An opening H1 may be buried within the insulating layer 120.

The substrate 101 may include a semiconductor material such as, for example, a Group IV semiconductor, a Group III-V compound semiconductor, or a Group II-VI oxide semiconductor. The Group IV semiconductor may include, for example, silicon (Si), germanium (Ge), or silicon-germanium (SiGe). The substrate 101 may be provided as, for example, a bulk wafer or an epitaxial layer. Further, the substrate 101 may be, for example, a silicon-on-insulator (SOI) layer or a semiconductor-on-insulator (SeOI) layer. The substrate 101 may include, for example, a semiconductor substrate and a portion of components of a semiconductor device formed on the semiconductor substrate. Further, the substrate 101 may include at least a portion of one or more semiconductor devices.

The semiconductor devices may be memory devices such as, for example, dynamic random access memory (DRAM) devices, static random access memory (SRAM) devices, spin transfer torque magnetic random access memory (STT-MRAM) devices, and flash memory devices, or non-memory devices such as logic devices. For example, the semiconductor devices may include a transistor, a resistor, or a wiring. Further, insulating elements for protecting the semiconductor devices such as, for example, a passivation layer may be formed on the substrate 101.

The substrate 101 may include a conductive region 110, and the conductive region 110 may be disposed such that it is exposed through an upper surface of the substrate 101. It is to be understood that the configuration of the conductive region 110 is illustrative, and the conductive region 110 may be any one of, for example, an impurity region, an electrode, a wiring, etc.

The insulating layer 120 may include the opening H1 exposing the conductive region 110. The opening H1 may be formed in a variety of shapes. For example, the opening H1 may have a hole shape or a line shape. In an exemplary embodiment in which the opening H1 has a line shape, the opening H1 may be formed such that it extends in a direction substantially perpendicular to the cross-section illustrated in FIG. 1. The opening H1 may have a tapered shape.

The insulating layer 120 may be formed of an insulating material such as, for example, a silicon oxide (SiO₂). Further, the insulating layer 120 may be any one of, for example, a high temperature oxide (HTO), a high density plasma (HDP) oxide, a tetra ethyl ortho silicate (TEOS), a boro-phospho-silicate glass (BPSG), or an undoped silicate glass (USG).

The conductive layer 130 may be buried within the opening H1 of the insulating layer 120. The conductive layer 130 may include a conductive material. The conductive layer 130 may include a first region 132 grown on inner side walls of the insulating layer 120, and a second region 134 grown on an inner surface of the first region 132 such that the second region 134 is disconnected from the first region 132. That is, in an exemplary embodiment, the second region 134 may be isolated from the first region 132, and disposed within the first region 132. As shown in FIG. 1, in an exemplary embodiment, the first region 132 may be disposed such that it covers lateral and lower surfaces of the insulating layer 120 within the opening H1, and the second region 134 may be disposed such that lateral and lower surfaces thereof are surrounded by the first region 132 in an upper portion of the opening H1. The lateral surfaces refer to the surfaces of the insulating layer 120 and the second region 134, respectively, that extend between the upper and lower surfaces of the insulating layer 120 in the cross-section illustrated in FIG. 1. Ends of the lateral surfaces of the second region 134 meet with ends of the lower surfaces of the second region 134, as shown in FIG. 1. In an exemplary embodiment, a width of the second region 134 increases from an upper surface of the conductive layer 130 toward ends of the lateral surfaces of the second region 134, and decreases from the ends of the lateral surfaces toward a lowermost point of the second region 134. Ends of the lower surfaces of the second region 134 meet ends of the lateral surfaces of the second region 134, respectively, and opposing ends of the lower surfaces of the second region 134 meet each other at the lowermost point of the second region 134. In an exemplary embodiment, all surfaces of the second region 134 other than an upper surface thereof may be surrounded by the first region 132 in the upper portion of the opening H1.

In an exemplary embodiment, the first and second regions 132 and 134 may be formed of the same material, and the first and second regions 132 and 134 may be formed through different growth processes and may have disconnected microstructures. Herein, disconnected microstructures may refer to disconnected crystal structures such as, for example, crystal grains, as described in further detail with reference to FIG. 2.

The conductive layer 130 may have a high aspect ratio. For example, the aspect ratio of the conductive layer 130 may range from about 1:5 to about 1:30. The conductive layer 130 may have a first width W1 at an upper surface thereof, a second width W2 smaller than or about equal to the first width W1 at a lower surface thereof, and a third width W3 greater than the first and second widths W1 and W2 between the upper and lower surfaces thereof. Accordingly, the conductive layer 130 may have a bowing region formed between the upper and lower surfaces thereof. The bowing region may designate a region having the third width W3 as a maximum width of the conductive layer 130 and a peripheral region thereof. In an exemplary embodiment, the bowing region may be positioned in an upper region of the entirety of the conductive layer 130, and, for example, may be positioned at a height greater than a middle height of the conductive layer 130. That is, as shown in FIG. 1, in an exemplary embodiment, the bowing region may be positioned in a portion of the top half of the conductive layer 130. The bowing region of the conductive layer 130 may be formed according to a movement of an etchant within the opening H1 having a high aspect ratio.

The conductive layer 130 may have a first depth D1 and a second depth D2. The second region 134 may have a width that increases from the upper surface of the conductive layer 130, and decreases from the second depth D2 toward a lowermost point L. In an exemplary embodiment, the lowermost point L, which corresponds to a point at which the second region 134 has its lowest level, may be positioned to be lower than a region having the third width W3, as shown in FIG. 1. The second depth D2 may be smaller than or about equal to about one-third of the first depth D1, however, exemplary embodiments are not limited thereto. A lateral surface of the conductive layer 130 may have a negative slope in an upper portion higher than the second depth D2, and a positive slope in a lower portion thereof. However, it is to be understood that angles of the slopes are not limited thereto, and may be varied according to, for example, process conditions or a size of the conductive layer 130.

FIG. 2 is a partially enlarged view schematically illustrating a semiconductor device according to an exemplary embodiment of the present inventive concept. More specifically, FIG. 2 is an enlarged view of the microstructures of region A shown in FIG. 1.

Referring to FIG. 2, the first and second regions 132 and 134 may include a plurality of first and second crystal grains G1 and G2, respectively. In an exemplary embodiment, the first and second regions 132 and 134 may be grown separately at different times such that they are disconnected from each other. An interface IF may be formed in which the plurality of first and second crystal grains G1 and G2 forming the first and second regions 132 and 134 are disposed contiguously. For example, in an exemplary embodiment, the interface IF may correspond to a common border shared by the pluralities of first and second grains G1 and G2 that form the first and second regions 132 and 134. In an exemplary embodiment, the first and second grains G1 and G2 are separated from each other at the interface IF. Crystal grains refer to an aggregation of crystal lattices grown from a single crystal nucleus, and crystal directions may be identical in a single crystal grain. Thus, at least a portion of a grain boundary of the first and second crystal grains G1 and G2 may lie in the interface IF.

As illustrated in FIG. 2, in an exemplary embodiment in which crystal grains of a material forming the conductive layer 130 have a columnar structure, the plurality of crystal grains G1 grown on the insulating layer 120 may be disconnected at the interface IF from the second region 134, and the second crystal grains G2 may be newly grown from the interface IF. The plurality of first and second crystal grains G1 and G2 may be formed in a direction toward the center of the opening H1 from inner side walls thereof (e.g., four rows in a direction substantially parallel to an upper surface of the substrate 101). In an exemplary embodiment, the plurality of second crystal grains G2 formed in the second region 134 may be disposed in two columns within the second region 134.

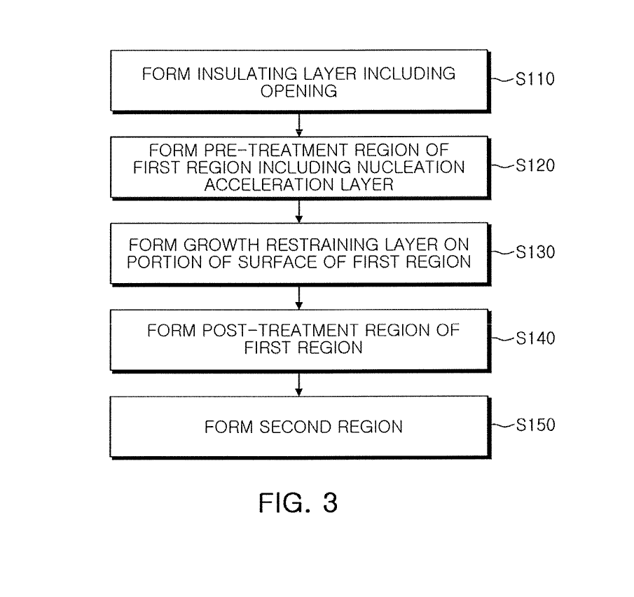

FIG. 3 is a flowchart illustrating a method of manufacturing a semiconductor device according to an exemplary embodiment of the present inventive concept.

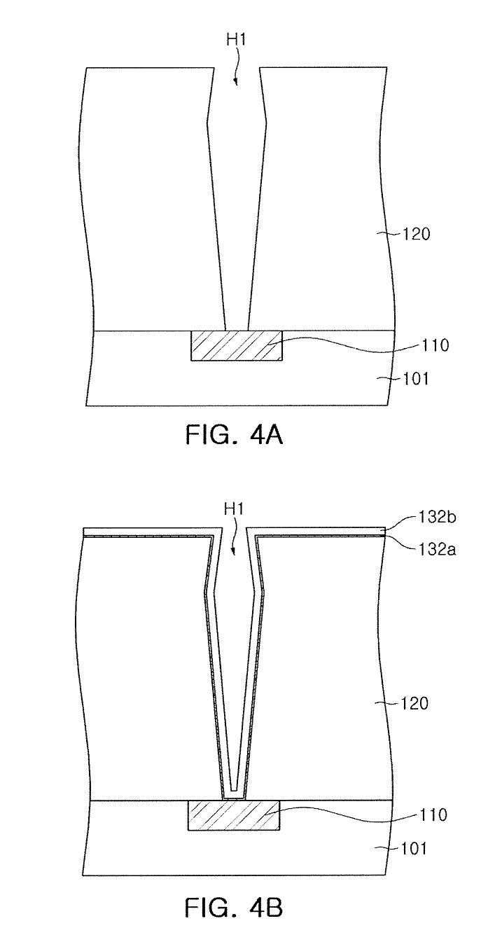

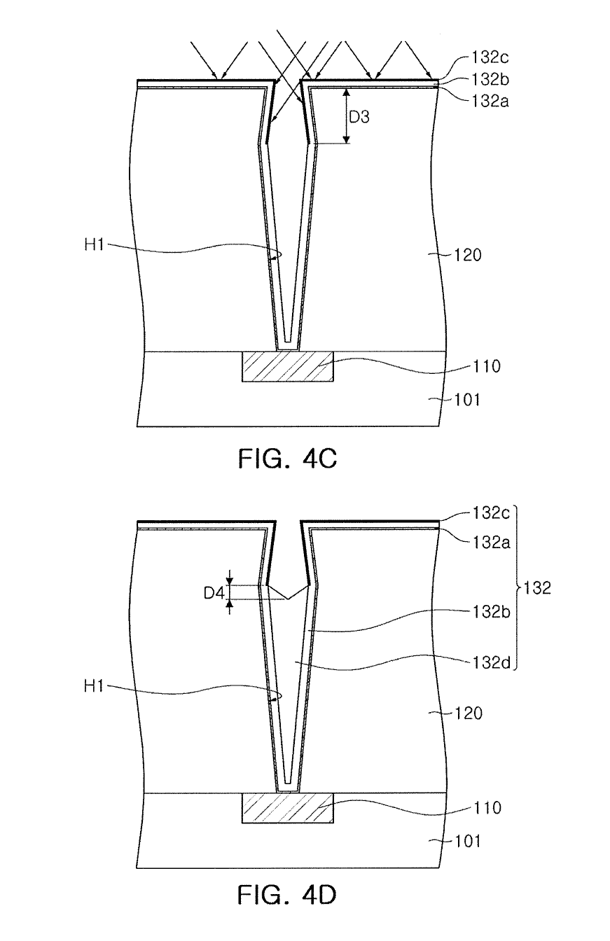

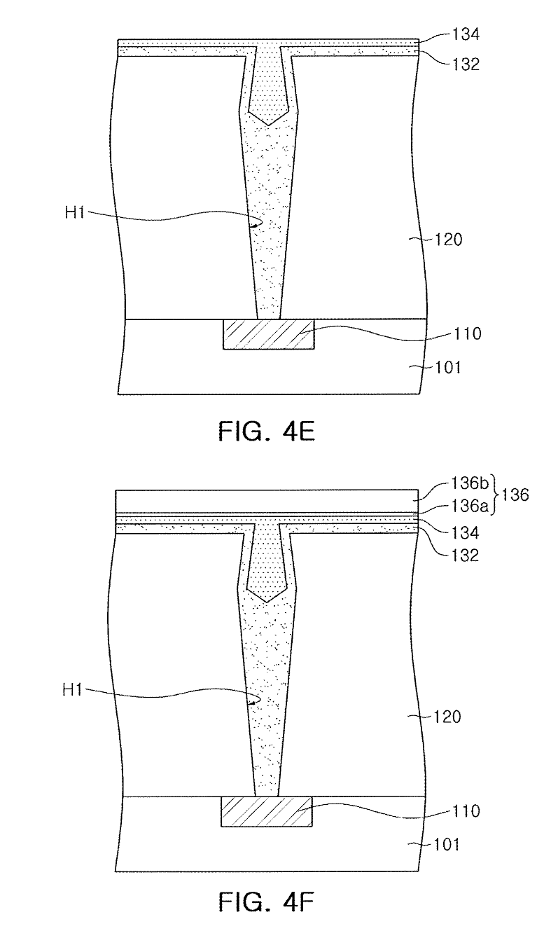

FIGS. 4A through 4F are cross-sectional views illustrating sequential processes of a method of manufacturing a semiconductor device according to an exemplary embodiment of the present inventive concept. In FIGS. 4A through 4F, like reference numerals with relation to those used in FIG. 1 may denote like elements, and further description of these elements may be omitted.

Referring to FIGS. 3 and 4A, the insulating layer 120 including the opening H1 may be formed on the substrate 101 in operation S110.

First, the insulating layer 120 may be formed using, for example, chemical vapor deposition (CVD). Next, a portion of the insulating layer 120 may be etched to be removed using a mask layer to form the opening H1. The mask layer may be, for example, a mask layer patterned through a photolithography process. The etching process may be, for example, an anisotropic etching process. For example, a reactive ion etching (RIE) process may be utilized. The etching process may also be performed using, for example, plasma.

The opening H1 may have a hole or a line shape, and an upper surface of the conductive region 110 of the substrate 101 may be exposed by the opening H1. As described above with reference to FIG. 1, the opening H1 may include a bowing region having a width that first increases and then decreases, and this configuration may be generated due to a flow of an etchant during formation of the opening H1. Further, according to an exemplary embodiment, the bowing region may be generated due to angles of patterned side walls of a mask layer used to form the opening H1.

Referring to FIGS. 3 and 4B, pre-treatment regions including first and second layers 132a and 132b of the first region 132 of the conductive layer 130 (see FIG. 1) are formed to cover the inner side walls of the opening H1 in operation S120.

The first layer 132a may be, for example, a nucleation acceleration layer that lowers the Gibbs free energy of a surface on which it is deposited, and increases reactivity to accelerate follow-up deposition of a material. The first layer 132a may be deposited using a gas including, for example, boron (B). Thereafter, the second layer 132b may be successively formed on the first layer 132a. The second layer 132b may be deposited using a gas different from that of the first layer 132a. In FIG. 4B, the first and second layers 132a and 132b are illustrated as being formed to have a uniform thickness on the inner side walls of the opening H1. However, in exemplary embodiments, according to a movement aspect of a deposited material, the first and second layers 132a and 132b may be formed to have a relatively greater thickness near the bowing region and the periphery thereof.

According to an exemplary embodiment, a barrier layer may be formed to prevent diffusion of an element of the conductive layer 130 prior to the formation of the first layer 132a.

Referring to FIGS. 3 and 4C, in an exemplary embodiment, a third layer 132c may be formed as a growth restraining layer on a portion of a surface of the first region 132 in operation S130.

The third layer 132c may be formed on a surface of the second layer 132b deposited on an upper surface of the opening H1, and may refer to a partial region of the second layer 132b in which surface treatment has been performed. The third layer 132c may act as a growth restraining layer that restrains deposition of a material thereon as a state of a surface functional group thereof is changed or as energy of the surface is changed. According to an exemplary embodiment, the third layer 132c may refer to a new film formed on the second layer 132b.

The third layer 132c may be formed only in an upper portion of a region in which the opening H1 has a maximum width. According to an exemplary embodiment, the third layer 132c may extend to a lower portion of this region by a predetermined length. Thus, a third depth D3 at which the third layer 132c is formed may be greater than or about equal to the second depth D2 shown in FIG. 1.

The third layer 132c may be formed using at least one process from among, for example, a plasma treatment, an ion implantation process, and a light source treatment. In an exemplary embodiment in which the third layer 132c is formed using a plasma treatment, at least one of gases from among, for example Ar, H₂, N₂, O₂, N₂, and NH₃ may be used. Further, a gas including at least one element from among, for example, chlorine (Cl), iron (F), carbon (C), oxygen (O), boron (B), and phosphorus (P) may be used. The plasma treatment may be performed as an in situ process with the process of forming the second layer 132b. In an exemplary embodiment, a plasma gas may reach obliquely at a predetermined angle from an upper portion of the insulating layer 120 to allow the third layer 132c to only be formed in an upper region of the second layer 132b.

Referring to FIGS. 3 and 4D, a post-treatment region including a fourth layer 132d disposed on the second layer 132b is formed in a lower portion of the opening H1 in operation S140.

In an exemplary embodiment in which a conductive material is deposited, since the conductive material is restrained from being deposited on the third layer 132c, the fourth layer 132d may be formed only on the second layer 132b in the lower portion of the opening H1. The first to fourth layers 132a, 132b, 132c, and 132d may constitute the first region 132 of the conductive layer 130. According to an exemplary embodiment, all of these layers may be formed of the same material. However, these layers may be individually designated herein for description purposes of a manufacturing method. The first region 132 may include, for example, tungsten (W) or aluminum (Al). In an exemplary embodiment, deposition of the conductive material may be performed under the same conditions before and after the formation of the third layer 132c, however, exemplary embodiments of the present inventive concept are not limited thereto.

The fourth layer 132d may include a bent region or a depressed region formed in an upper portion thereof. This configuration may be obtained due to a lower portion of the fourth layer 132d growing faster as a result of a growth restraining effect of the third layer 132c. In an exemplary embodiment, a fourth depth D4, which corresponds to the depth of the bent region, may be varied according to, for example, a depth, width, process conditions, etc., of the opening H1. In an exemplary embodiment, the fourth depth D4 may be approximately zero, and in this case, the fourth layer 132d may have a substantially flat upper surface.

Referring to FIGS. 3 and 4E, the second region 134 of the conductive layer 130 may be formed on the first region 132 of the conductive layer 130 within the opening H1 in operation S150.

After a predetermined time, when the growth restraining effect of the third layer 132c wears off, the second region 134 may be grown on the first region 132. Thus, since there is a discontinuation in growth between the first and second regions 132 and 134, the first and second regions 132 and 134 may have disconnected micro structures.

In an exemplary embodiment, since the first region 132 buried down to a lower portion of the bowing region including a region in which the opening H1 has a maximum width is first formed, and the second region 134 is formed in an upper portion thereof, formation of a void or a seam in the bowing region may be prevented.

Referring to FIG. 4F, in an exemplary embodiment, an upper conductive layer 136 including first and second layers 136a and 136b may be further formed above the opening H1.

The formation of the upper conductive layer 136 is optional. Thus, for example, in an exemplary embodiment in which the conductive layer 130 is being planarized to be aligned with an upper surface of the insulating layer 120, the upper conductive layer 136 may be additionally formed as needed. The first layer 136a of the upper conductive layer 136 may be formed as, for example, a nucleation accelerating layer, and the second layer 136b of the upper conductive layer 136 may be formed to have a desired thickness on the first layer 136a.

After the formation of the upper conductive layer 136, a planarization process such as, for example, chemical mechanical polishing (CMP) may be performed to form the conductive layer 130, as illustrated in FIG. 1.

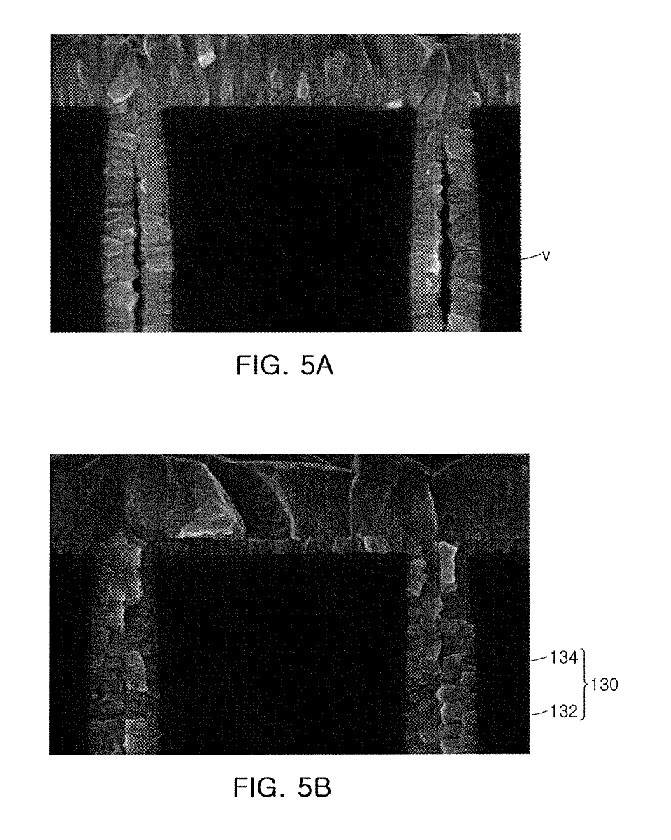

FIGS. 5A and 5B are electron microscope photographs illustrating a conductive layer that may be implemented in a semiconductor device according to an exemplary embodiment of the present inventive concept. More specifically, FIGS. 5A and 5B illustrate the results of analyzing cross-sections near the bowing region of the conductive layer formed of tungsten (W) through a scanning electron microscope (SEM).

Referring to FIGS. 5A and 5B, FIG. 5A illustrates a conductive layer formed through a single deposition process, and FIG. 5B illustrates the conductive layer 130 formed according to an exemplary embodiment of the present inventive concept as described above.

Referring to FIG. 5A, as a conductive material is substantially uniformly deposited, even in a bowing region, a void v is formed. In contrast, according to exemplary embodiments of the present inventive concept, the conductive layer 130 illustrated in FIG. 5B is divided into first and second regions 132 and 134, preventing formation of a void or a seam. In addition, as shown in FIG. 5B, the first and second regions 132 and 134 have microstructures disconnected therebetween.

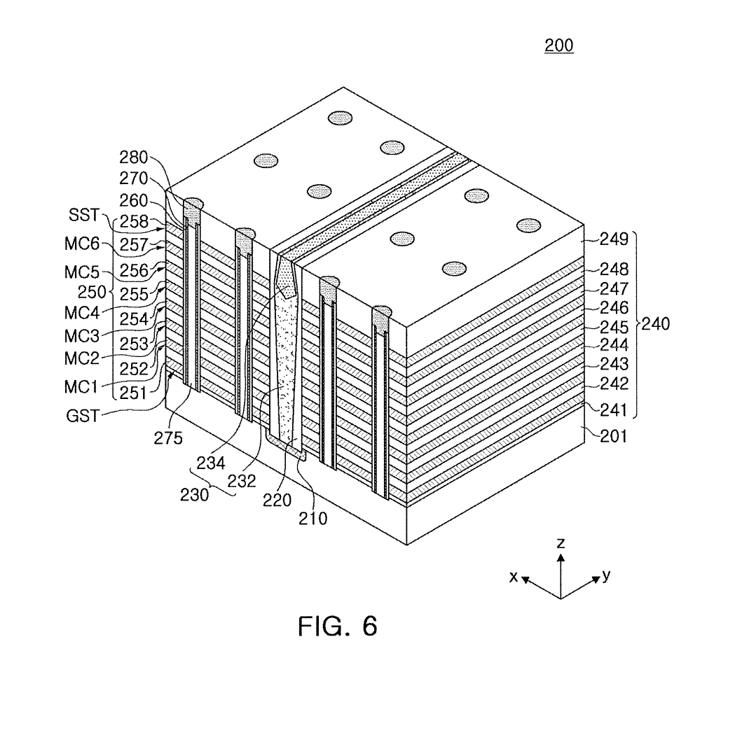

FIG. 6 is a perspective view schematically illustrating a semiconductor device according to an exemplary embodiment of the present inventive concept.

Referring to FIG. 6, a semiconductor device 200 may include channel regions 270 disposed in a direction substantially perpendicular to an upper surface of a substrate 201, and a plurality of interlayer insulating layers 240 and a plurality of gate electrodes 250 stacked along outer side walls of the channel regions 270. Further, the semiconductor device 200 may further include a gate dielectric layer 260 disposed between the gate electrodes 250 and each of the channel regions 270, and may include a common source line 230 disposed between the channel regions 270 and a bit line disposed above the channel regions 270.

The semiconductor device 200 may be, for example, a non-volatile memory device. In the semiconductor device 200, a single memory cell string may be configured with each channel region 270 as a center portion, and a plurality of memory cell strings may be arranged in rows and columns in x and y directions.

The substrate 201 may have an upper surface extending in the x and y directions. The substrate 201 may include a semiconductor material such as, for example, a Group IV semiconductor, a Group III-V compound semiconductor, or a Group II-VI oxide semiconductor. The Group IV semiconductor may include, for example, silicon, germanium, or silicon-germanium. The substrate 201 may be provided, for example, as a bulk wafer or an epitaxial layer.

The columnar channel regions 270 may be disposed to extend in a direction substantially perpendicular to the upper surface of the substrate 201. The channel regions 270 may each have an annular shape surrounding a buried insulating layer 275 disposed therein, however, exemplary embodiments are not limited thereto. For example, in exemplary embodiments, the channel regions 270 may have a columnar shape such as, for example, a cylindrical shape or a prismatic shape without the buried insulating layer 275. Further, the channel regions 270 may have a sloped lateral surface that becomes more narrow toward the substrate 201 according to an aspect ratio.

The channel regions 270 may be disposed to be spaced apart from one another in the x and y directions, however, exemplary embodiments are not limited thereto. For example, according to exemplary embodiments, the channel regions 270 may be variously disposed. For example, in an exemplary embodiment, the channel regions 270 may be disposed in a zigzag pattern in at least one direction. Further, the channel regions 270 adjacent to an isolation insulating layer 220 interposed therebetween may be symmetrical, however, exemplary embodiments are not limited thereto.

Lower surfaces of the channel regions 270 may be directly contiguous with the substrate 201 so as to be electrically connected thereto. The channel regions 270 may include a semiconductor material such as, for example, polysilicon or single crystalline silicon, and the semiconductor material may be an undoped material or a material including a p-type or n-type impurity.

The plurality of gate electrodes 250, which includes gate electrodes 251 to 258, may be disposed to be spaced apart from one another in the z direction along the lateral surfaces of the channel regions 270 from the substrate 201. Each of the gate electrodes 250 may form a gate of each of a ground select transistor GST, a plurality of memory cells MC1 to MC6, and a string select transistor SST. The gate electrodes 250 may extend to form word lines, and may be commonly connected in a predetermined unit of adjacent memory strings arranged in the x and y directions. In FIG. 6, six gate electrodes 252 to 257 of the memory cells MC1 to MC6 are arranged, however, this configuration is illustrative, and the number of the gate electrodes 252 to 257 constituting the memory cells MC1 to MC6 is not limited thereto. For example, the number of the gate electrodes 252 to 257 constituting the memory cells MC1 to MC6 may be determined according to the capacity of the semiconductor device 200. For example, the number of gate electrodes 252 to 257 constituting the memory cells MC1 to MC6 may be 2ⁿ (n is a natural number).

The gate electrode 251 of the ground select transistor GST may extend in the y direction to form a ground select line. The gate electrode 258 of the string select transistor SST may extend in the y direction to form a string select line. The gate electrode 258 of the string select transistor SST may be separated between the memory cell strings adjacent in the x direction in a region to form different string select lines. According to an exemplary embodiment, the string select transistor SST may have two or more gate electrodes 258 and the ground select transistor GST may have two or more gate electrodes 251, and the two or more gate electrodes 258 and the two or more gate electrodes 251 may have a structure different from that of the gate electrodes 252 to 257 of the memory cells MC1 to MC6.

The gate electrodes 250 may include, for example, polysilicon or metal silicide material. The metal silicide material may be silicide material of a metal selected from among, for example, cobalt (Co), nickel (Ni), hafnium (Hf), platinum (Pt), tungsten (W), and titanium (Ti). According to an exemplary embodiment, the gate electrodes 250 may include a metal such as, for example, tungsten (W). Further, the gate electrodes 250 may further include a diffusion barrier. The diffusion barrier may include, for example, at least one of tungsten nitride (WN), tantalum nitride (TaN), and titanium nitride (TiN).

The plurality of interlayer insulating layers 240, which includes interlayer insulating layers 241 to 249, may be arranged between the gate electrodes 250. Similar to the gate electrodes 250, the interlayer insulating layers 240 may be arranged to be spaced apart from one another in the z direction and may extend in the y direction. The interlayer insulating layers 240 may include an insulating material such as, for example, silicon oxide or silicon nitride.

The gate dielectric layer 260 may be disposed between the gate electrodes 250 and the channel region 270. The gate dielectric layer 260 may include, for example, a tunneling layer, an electric charge storage layer, and/or a blocking layer sequentially stacked on the channel region 270.

The tunneling layer may tunnel electric charges to the electric charge storage layer in a Fowler-Nordheim (F-N) manner. The tunneling layer may include, for example, a silicon oxide. The electric charge storage layer may be an electric charge trap layer or a floating gate conductive layer. For example, the electric charge storage layer may include a dielectric material, quantum dots, or nanocrystals. The quantum dots or the nanocrystals may be formed of microparticles of a conductor such as, for example, a metal or a semiconductor. The blocking layer may include a high-k dielectric material. The high-k dielectric material refers to a dielectric material having a dielectric constant higher than that of a silicon oxide film.

In an upper end of the memory cell string, a drain region 280 may be disposed to cover an upper surface of the buried insulating layer 275 and may be electrically connected to the channel region 270. The drain region 280 may include, for example, doped polysilicon. The drain region 280 may act as a drain region of the string select transistor SST.

A bit line may be further disposed in an upper portion of the drain region 280. The bit line may extend to be connected to the drain regions 280 alternately selected from among a row of drain regions 280 arranged in the x direction on upper portions of the drain regions 280.

Source regions 210 of the ground select transistors GST (see FIG. 2) arranged in the x direction may be disposed in lower ends of the memory cell strings. The source regions 210 may be adjacent to the upper surface of the substrate 201, extend in the y direction, and be spaced apart from one another by a predetermined unit in the x direction. For example, one source region 210 may be arranged in every two channel regions 270 in the x direction, however, exemplary embodiments of the present inventive concept are not limited thereto. An isolation insulating layer 220 may be formed on each source region 210. The common source line 230 may be disposed in the opening within the isolation insulating layer 220. Herein, the source regions 210 may also be referred to as conductive regions, the isolation insulating layer 220 may also be referred to as an insulating layer, and the common source line 230 may also be referred to as a common source layer.

The common source line 230 may extend in the y direction on the source region 210, and may be arranged to be in ohmic-contact with the source region 210. The common source line 230 may have a line shape having a high aspect ratio. For example, the common source line 230 may have an aspect ratio ranging from about 1:10 to about 1:30. In an exemplary embodiment, the common source line 230 may be disposed in the form of at least one contact having a pillar shape. The common source line 230 may have a bowing region formed between upper and lower surfaces thereof. For example, the common source line 230 may include tungsten (W), aluminum (Al), or copper (Cu). The isolation insulating layer 220 is formed on the lateral surfaces of the common source line 230 so as to be insulated from the gate electrodes 250. An insulating material such as, for example, the ninth interlayer insulating layer 249, may be disposed in an upper surface of the common source line 230.

The common source line 230 may include a first region 232 grown on inner side walls of the opening of the isolation insulating layer 220 and a second region 234 grown on an inner surface of the first region 232 such that the second region 234 is disconnected from the first region 232. The first region 232 may be disposed to cover the inner walls of the isolation insulating layer 220, and the second region 234 may be disposed such that lateral and lower surfaces thereof are surrounded by the first region 232. The first and second regions 232 and 234 may be formed through different growth processes to have disconnected microstructures. Even in a case in which an aspect ratio of the common source line 230 is increased according to an increase in the number of memory cells MC1-MC6, the common source line 230 may be formed to include the first and second regions 232 and 234, and may be formed without a void.

Referring to FIG. 6, in an exemplary embodiment, a semiconductor device includes the substrate 201, which includes a conductive region (e.g., the source region 210). The plurality of channel regions 270 extend in a direction substantially perpendicular to the upper surface of the substrate 201. The plurality of gate electrodes 250 and the plurality of interlayer insulating layers 240 are alternately stacked on the substrate 201 along outer side walls of the plurality of channel regions 270. An insulating layer (e.g., the isolation insulating layer 220) includes an opening exposing the conductive region and disposed between adjacent channel regions of the plurality of channel regions 270. A common source layer (e.g., the common source line 230) is buried within the opening, and includes the first region 232 that is grown on a lateral surface of the insulating layer, and the second region 234 that is grown on a lateral surface of the first region 232. The first and second regions 232 and 234 are disconnected from each other.

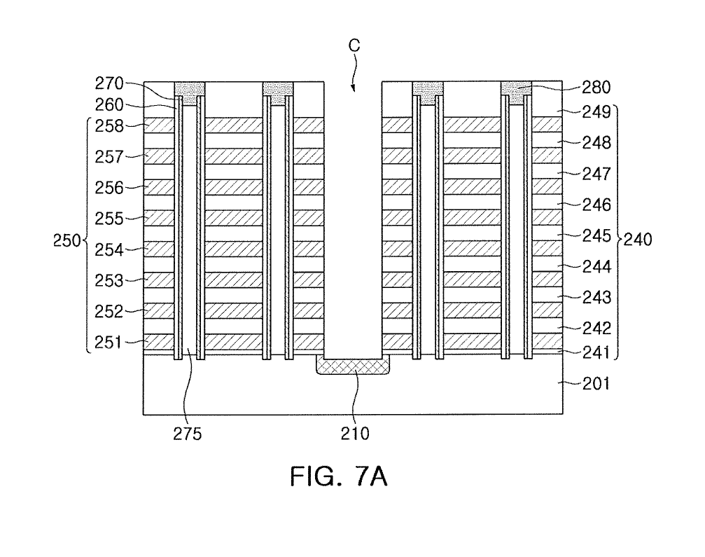

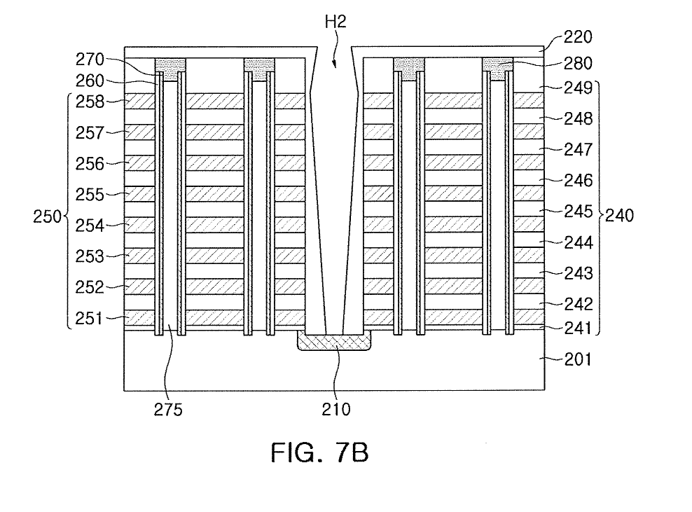

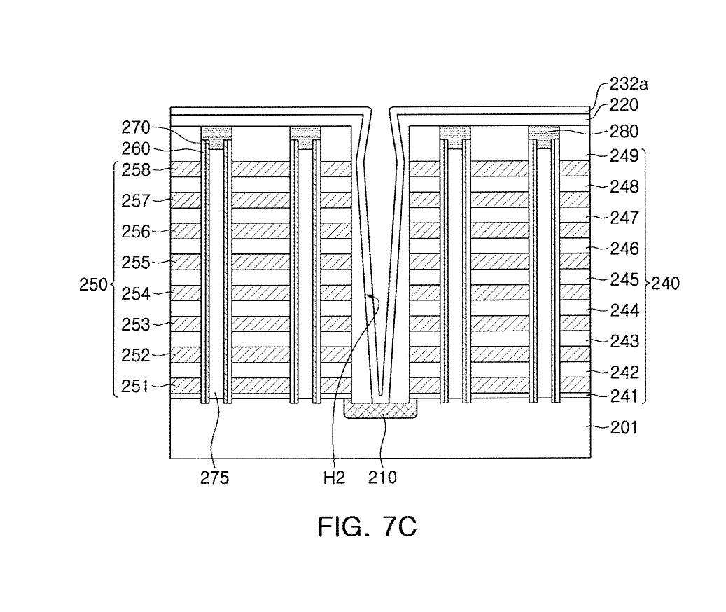

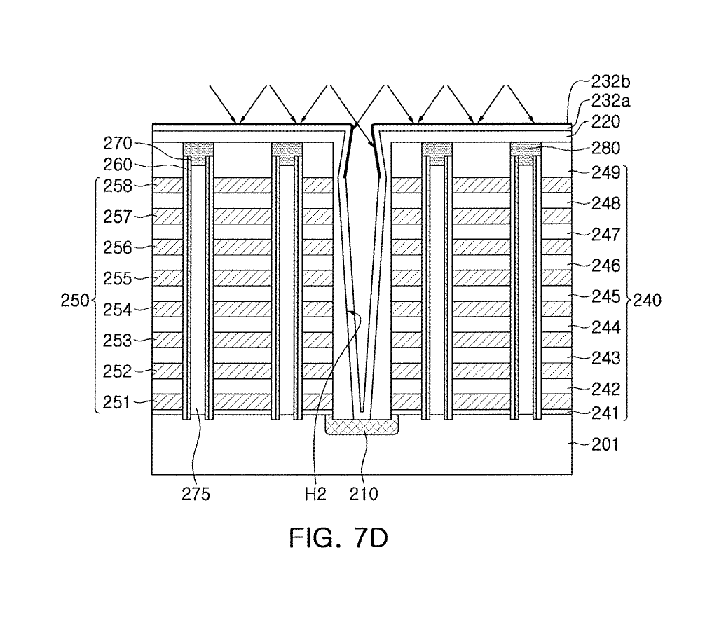

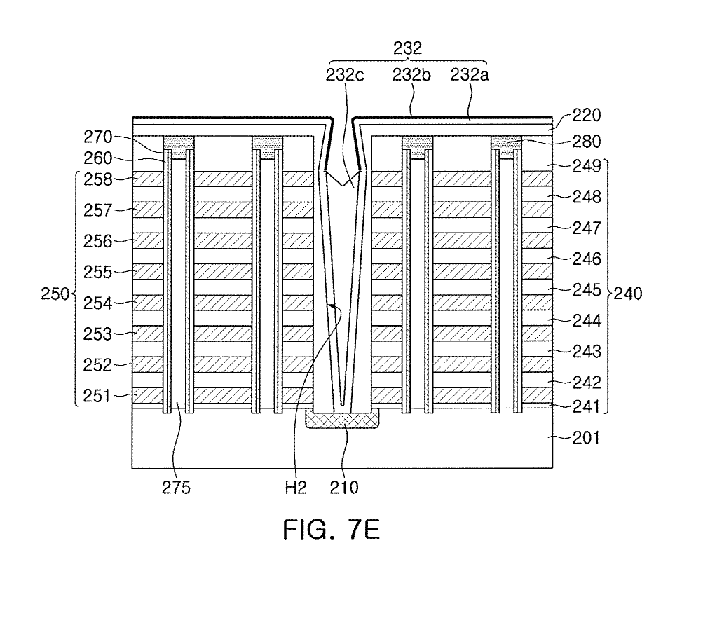

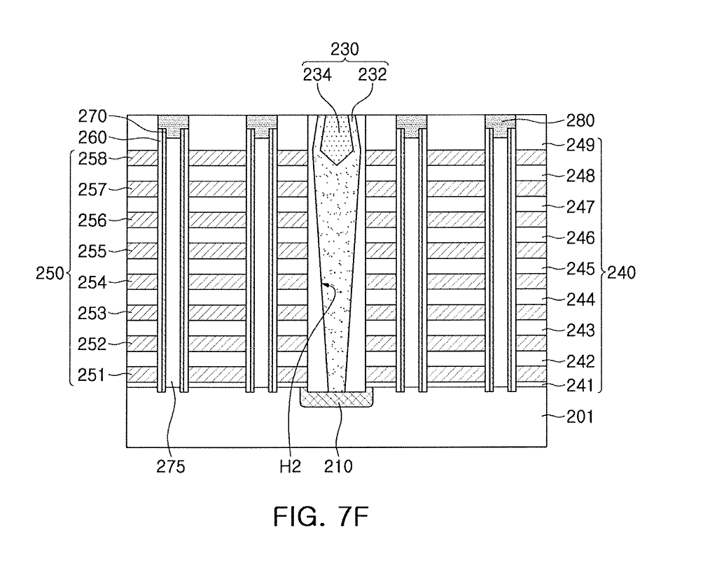

FIGS. 7A through 7F are cross-sectional views illustrating processes of a method of manufacturing a semiconductor device according to an exemplary embodiment of the present inventive concept. In FIGS. 7A through 7F, like reference numerals with relation to those used in FIG. 6 may denote like elements, and further description of these elements may be omitted.

Referring to FIG. 7A, a plurality of interlayer insulating layers 240 and a plurality of gate electrodes 250 may first be alternately stacked. Next, channel regions 270 penetrating through the plurality of stacked interlayer insulating layers 240 and the plurality of stacked gate electrodes 250 may be formed to be spaced apart from one another at predetermined intervals. A gate dielectric layer 260 may be disposed between each channel region 270 and the gate electrodes 250, a buried insulating layer 275 may be formed within each channel region 270, and a drain region 280 may be formed on each buried insulating layer 275.

Thereafter, the gate electrodes 250 may be separated by a predetermined interval to form an isolation opening C exposing a substrate 201 between the channel regions 270. The isolation opening C may have a line shape extending in the y direction, and at least one isolation opening C may be formed in each channel region 270 in the x direction between the channel regions 270. A source region 210 having a predetermined depth may be formed in an upper portion of the substrate 201 exposed through the isolation opening C. According to exemplary embodiments, the source region 210 may be formed as a high concentration doped region through, for example, ion implantation, or the source region 210 may be formed as a silicide region by forming a metal layer in an upper portion thereof and subsequently performing heat treatment. According to an exemplary embodiment, the plurality of gate electrodes 250 may also be made into silicide along with the source region 210 during this process.

Referring to FIG. 7B, the isolation opening C may be buried with an insulating material to form an isolation insulating layer 220, and an opening H2 may be formed within the isolation insulating layer 220.

An insulating material may first be deposited using, for example, CVD to form an insulating material layer. The insulating material layer may bury the isolation opening C and may also be formed in upper portions of the plurality of stacked interlayer insulating layers 240 and the plurality of stacked gate electrodes 250.

The opening H2 may be formed by etching and removing a portion of the insulating material layer using a mask layer. The mask layer may be a mask layer patterned through, for example, a photolithography process. The etching process may be, for example, an anisotropic etching process. For example, a reactive ion etching (RIE) process may be utilized. The etching process may also be performed using, for example, plasma.

The opening H2 may have a line shape. An upper surface of the source region 210 may be exposed by the opening H2. The opening H2 may include a bowing region having a width that first increases from an upper portion thereof and then decreases. It is to be understood the height of the bowing region is not limited to that the height shown in FIG. 7B. For example, according to exemplary embodiments, the height of the bowing region may be varied.

Referring to FIG. 7C, a pre-treatment region 232a of the first region 232 (see FIG. 6) may be formed to cover inner side walls of the opening H2.

The pre-treatment region 232a may include a nucleation acceleration layer contiguous with the inner side walls of the opening H2. Further, according to exemplary embodiments, the pre-treatment region 232a may be deposited to have a uniform thickness on the inner side walls of the opening H2 or may be deposited to be relatively thick in the bowing region and the periphery thereof.

Referring to FIG. 7D, a growth restraining layer 232b may be formed on a portion of a surface of the pre-treatment region 232a.

The growth restraining layer 232b may refer to a partial region of the pre-treatment region 232a surface-treated to have changed surface qualities. The growth restraining layer 232b may act as a growth restraining layer that restrains deposition of a material thereon as a state of a surface functional group thereof is changed or as energy of the surface is changed. According to an exemplary embodiment, the growth restraining layer 232b may refer to a new film formed on the pre-treatment region 232a.

The growth restraining layer 232b may be formed using at least one process from among, for example, a plasma treatment process, an ion implantation process, and a light source treatment process. In an exemplary embodiment in which the growth restraining layer 232b is formed through a plasma treatment process, a plasma gas may reach obliquely at a predetermined angle from an upper portion of the isolation insulating layer 220, and a depth of the growth restraining layer 232b may be adjusted when formed by process conditions such as, for example, bias. For example, in an exemplary embodiment, the growth restraining layer 232b may be formed only in an upper portion of a region in which the opening H2 has a maximum width. According to an exemplary embodiment, the growth restraining layer 232b may also extend to a lower portion of the region of the opening H2 having the maximum width to have a predetermined length. For example, in an exemplary embodiment, the growth restraining layer 232b may be formed in a portion of the bowing region and an upper portion thereof.

Referring to FIG. 7E, a post-treatment region 232c of the first region 232 may be formed in a lower portion of the opening H2, thus forming the first region 232.

In an exemplary embodiment in which a conductive material is deposited, the conductive material is restrained from being deposited on the growth restraining layer 232b or deposited at a relatively low rate, such that the post-treatment region 232c may only be formed in the lower pre-treatment region 232a in the lower portion of the opening H2. In this case, the post-treatment region 232c may be formed as an in situ process with the formation of the growth restraining layer 232b, and thus, the post-treatment region 232c may be successively grown without being separated from microstructures of the pre-treatment region 232a. This may be because only temporal discontinuation in terms of process exists between the pre-treatment region 232a and the post-treatment region 232c.

The pre-treatment region 232a, the growth restraining layer 232b, and the post-treatment region 232c may constitute the first region 232 of the conductive layer 230, and may all be formed of the same material. The first region 232 may include, for example, tungsten (W) or aluminum (W).

The post-treatment region 232c may include a depressed region formed in an upper portion thereof. This configuration may be obtained because a lower portion of the post-treatment region 232c grows faster due to an influence of a growth restraining effect of the growth restraining layer 232b.

Referring to FIG. 7F, the second region 234 may be formed on the first region 232 within the opening H2 to form the common source line 230.

After a predetermined time, when the growth restraining effect of the growth restraining layer 232b wears off, the second region 234 may be grown on the first region 232. Thus, the second region 234 may not be successively grown on the growth restraining layer 232b of the first region 232, since the surface qualities have been changed by the growth restraining layer 232b. Thus, the second region 234, which is not successively grown on the first region 232, may have disconnected microstructures.

In an exemplary embodiment, since the first region 232 buried down to a lower portion of the bowing region including a region in which the opening H2 has a maximum width is first formed, and since the second region 234 is formed in an upper portion thereof, formation of a void in the bowing region may be prevented.

Thereafter, a planarization process may be performed on upper portions of the laminate structures of the plurality of interlayer insulating layers 240 and the plurality of gate electrodes 250 to remove materials of the isolation insulating layer 220 and the common source line 230 remaining in the upper portions. The planarization process may also be performed after the upper conductive layer 136 is additionally formed as described above with reference to FIG. 4F.

Thereafter, a connection structure such as, for example, a bit line plug connected to the drain region 280 and a bit line may be further formed.

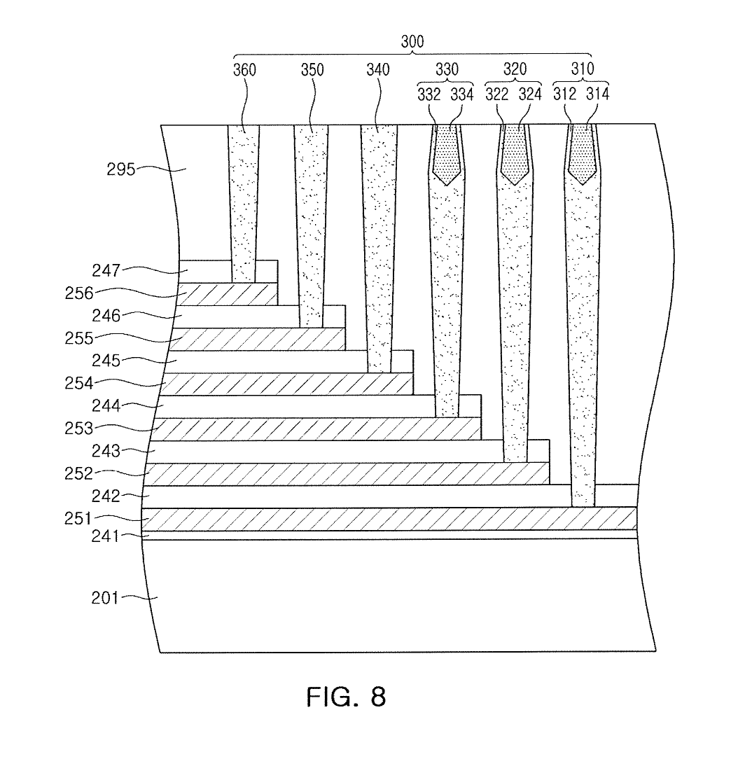

FIG. 8 is a cross-sectional view illustrating a semiconductor device according to an exemplary embodiment of the present inventive concept.

Referring to FIG. 8, a portion of a connection region connecting a cell region in which memory cells are disposed, and a peripheral circuit region in which elements driving the cell region are disposed in the semiconductor device 200 as illustrated in FIG. 6, is illustrated.

In the connection region, an insulating layer 295 is disposed in an upper portion of a laminate structure in which gate electrodes 251 to 256 and interlayer insulating layers 241 to 247 are stacked, and a plurality of contact plugs 300, including contact plugs 310 to 360, may be connected to the gate electrodes 251 to 256, respectively. The contact plugs 300 may be a portion of a wiring structure for connecting the gate electrodes 251 to 256 to driving circuits of the peripheral circuit region.

The contact plugs 300 may pass through the insulating layer 295 to be connected to the gate electrodes 251 to 256, respectively. First to third contact plugs 310, 320, and 330 connected to first to third gate electrodes 251, 252, and 253 disposed in a lower side among the contact plugs 300 may have a higher aspect ratio than that of the fourth to sixth contact plugs 340, 350, and 360 connected to the fourth to sixth gate electrodes 340, 350, and 360 disposed in a relative upper side. Thus, when a contact hole for formation of the first to third contact plugs 310, 320, and 330 is formed, a bowing region may be formed. It is to be understood that the formation of a bowing region in the first to third contact plugs 310, 320, and 330 is illustrative, and the number of contact plugs 300 in which a bowing region is formed is not limited thereto. Further, bowing regions formed in the first to third contact plugs 310, 320, and 330, as well as additional contact plugs, may have different heights.

Each of the first to third contact plugs 310, 320, and 330 may include first regions 312, 322, and 332, and second regions 314, 324, and 334. This structure may be obtained, for example, by opening only regions corresponding to the first to third contact plugs 310, 320, and 330 and forming the growth restraining layer as described above with reference to FIGS. 3 and 4C thereon when forming the first to third contact plugs 310, 320, and 330.

The first regions 312, 322, and 332 may be disposed on side walls of the openings within the openings, and the second regions 314, 324, and 334 may be disposed on inner surfaces of the first regions 312, 322, and 332. The second regions 314, 324, and 334 may be disposed such that lateral and lower surfaces thereof are surrounded by the first regions 312, 322, and 332, respectively. Since the first regions 312, 322, and 332, and the second regions 314, 324, and 334, are formed through different growth processes, they may have mutually disconnected microstructures. Relative thicknesses of the first regions 312, 322, and 332, and the second regions 314, 324, and 334 are not limited to those illustrated in FIG. 8. For example, according to exemplary embodiments, the first regions 312, 322, and 332 may be formed to be thicker than those illustrated in lateral surfaces of the second regions 314, 324, and 334.

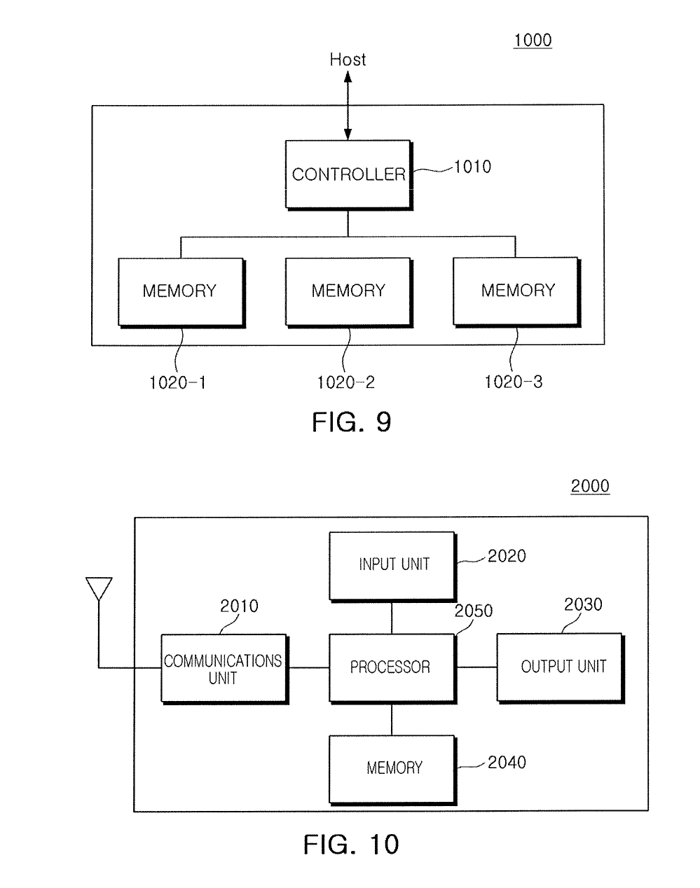

FIG. 9 is a block diagram illustrating a storage device including a semiconductor device according to an exemplary embodiment of the present inventive concept.

Referring to FIG. 9, a storage device 1000 may include a controller 1010 communicating with a host and memories 1020-1, 1020-2, and 1020-3 storing data. Each of the memories 1020-1, 1020-2, and 1020-3 may include the semiconductor devices according to exemplary embodiments of the present inventive concept as described above.

The host communicating with the controller 1010 may be one of various electronic devices in which the storage device 1000 is installed. For example, the host may be a smartphone, a digital camera, a desktop computer, a laptop computer, a media player, etc. When a data write or read request is received from the host, the controller 1010 may store data in the memories 1020-1, 1020-2, and 1020-3, or generate a command CMD to retrieve data from the memories 1020-1, 1020-2, and 1020-3.

As illustrated in FIG. 9, one or more memories 1020-1, 1020-2, and 1020-3 may be connected to the controller 1010 in parallel within the storage device 1000. By connecting the plurality of memories 1020-1, 1020-2, and 1020-3 to the controller 1010 in parallel, the storage device 1000 having a large capacity such as, for example, a solid state drive (SSD), may be implemented.

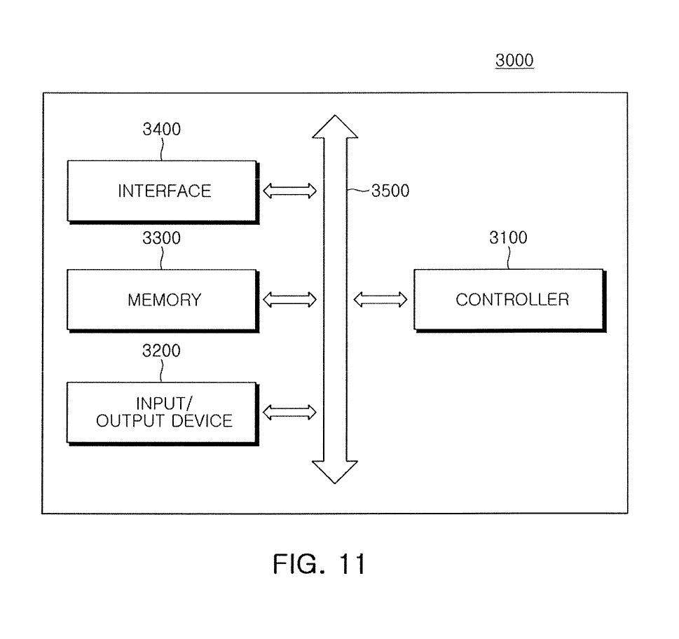

FIG. 10 is a block diagram illustrating an electronic device including a semiconductor device according to an exemplary embodiment of the present inventive concept.

Referring to FIG. 10, an electronic device 2000 according to an exemplary embodiment may include, for example, a communications unit 2010, an input unit 2020, an output unit 2030, a memory 2040, and a processor 2050.

The communications unit 2010 may include a wired/wireless communications module such as, for example, a wireless Internet module, a short-range communications module, a global positioning system (GPS) module, a mobile communications module, etc. A wired/wireless communications module included in the communications unit 2010 may be connected to an external communication network using various communication standards to transmit and receive data.

The input unit 2020 allows a user to control an operation of the electronic device 2000, and may include, for example, a mechanical switch, a touchscreen, a voice recognition module, a mouse, various sensor modules allowing the user to input data, etc.

The output unit 2030 outputs information processed in the electronic device 2000 in, for example, an audio or video format, and the memory 2040 may store a program for processing and controlling the processor 2050, data, etc. The memory 2040 may include one or more semiconductor devices according to exemplary embodiments of the present inventive concept as described above. The processor 2050 may deliver a command to the memory 2040 according to a necessary operation in order to store data in the memory 2040 or retrieve data from the memory 2040.

The memory 2040 may be installed in the electronic device 2000 or may communicate with the processor 2050 through a separate interface. In an exemplary embodiment in which the memory 2040 communicates with the processor 2050 through a separate interface, the processor 2050 may store data in the memory 2040 or retrieve data from the memory 2040 through various interface standards such as, for example, SD, SDHC, SDXC, MICRO SD, USB, etc.

The processor 2050 controls operations of respective components included in the electronic device 2000. The processor 2050 may perform controlling and processing related to, for example, an audio call, a video call, data communication, multimedia playback and management, etc. Further, the processor 2050 may process an input delivered from the user through the input unit 2020 and may output corresponding results through the output unit 2030. Further, the processor 2050 may store data required for controlling an operation of the electronic device 2000 to the memory 2040 or may retrieve such data from the memory 2040.

FIG. 11 is a view schematically illustrating an electronic system including a semiconductor device according to an exemplary embodiment of the present inventive concept.

Referring to FIG. 11, an electronic system 3000 may include a controller 3100, an input/output device 3200, a memory 3300, and an interface 3400. The electronic system 3000 may be, for example, a mobile system or any other type of system that transmits and receives information. The mobile system may be, for example, a smartphone, a personal digital assistant (PDA), a portable computer, a computer tablet, a wireless phone, a mobile phone, a digital music player, a memory card, etc.

The controller 3100 serves to execute a program and to control the electronic system 3000. The controller 3100 may be, for example, a microprocessor, a digital signal processor, a microcontroller, etc.

The input/output device 3200 may be used to input or output data in the electronic system 3000. The electronic system 3000 may be connected to an external device such as, for example, a personal computer or a network, and may exchange data using the input/output device 3200. The input/output device 3200 may be, for example, a keypad, a keyboard, a display, etc.

The memory 3300 may store codes and/or data for an operation of the controller 3100, and/or store data processed by the controller 3100. The memory 3300 may include, for example, a non-volatile memory according to any one of the exemplary embodiments of the present inventive concept.

The interface 3400 may serve as a data transmission passage between the electronic system 3000 and an external device. The controller 3100, the input/output device 3200, the memory 3300, and the interface 3400 may communicate through a bus 3500.

At least one of the controller 3100 and the memory 3300 may include one or more semiconductor devices according to exemplary embodiments of the present inventive concept as described above.

As set forth above, according to exemplary embodiments of the present inventive concept, a semiconductor device, in which formation of a void is prevented by disposing regions having different microstructures in a conductive layer having a high aspect ratio in a stacked manner, is provided. The configuration of the semiconductor device according to exemplary embodiments may result in reducing a defect rate, and thus, reducing connection resistivity of the conductive layer and improving reliability.

While the present inventive concept has been particularly shown and described with reference to the exemplary embodiments thereof, it will be understood by those of ordinary skill in the art that various changes in form and detail may be made therein without departing from the spirit and scope of the present inventive concept as defined by the following claims.

What is claimed is:

1. A semiconductor device, comprising:
a substrate comprising a conductive region;
an insulating layer disposed on the substrate and comprising an opening exposing the conductive region; and
a conductive layer buried within the opening and comprising a first region disposed on inner side walls of the opening and a second region disposed within the first region,
wherein the first region comprises a plurality of first crystal grains and the second region comprises a plurality of second crystal grains, and the pluralities of first and second crystal grains are separated from each other at a boundary formed between the first and second regions.

2. The semiconductor device of claim 1, wherein the second region is disposed in an upper portion of the opening, and lateral surfaces and lower surfaces of the second region are surrounded by the first region.

3. The semiconductor device of claim 1, wherein a width of the second region increases from an upper surface of the insulating layer toward a predetermined depth, and decreases from the predetermined depth toward a lowermost point of the second region.

4. The semiconductor device of claim 1, wherein the plurality of first crystal grains is grown in one direction toward a center of the opening, and the plurality of second crystal grains is grown in the one direction from the boundary with the first region.

5. The semiconductor device of claim 4, wherein the pluralities of first and second crystal grains have a columnar structure grown in the one direction.

6. The semiconductor device of claim 4, wherein the plurality of second crystal grains are disposed in two columns within the second region.

7. The semiconductor device of claim 1, wherein the conductive layer comprises a bowing region formed between an upper surface and a lower surface of the conductive layer, wherein the conductive layer has a first width at the upper surface, a second width less than the first width at the lower surface, and a third width greater than the first width at the bowing region.

8. The semiconductor device of claim 7, wherein the second region extends at least to the bowing region from the upper surface of the conductive layer.

9. The semiconductor device of claim 7, wherein a width of the second region increases from the upper surface of the conductive layer toward the bowing region and decreases at a lower portion of the bowing region.

10. The semiconductor device of claim 7, wherein the bowing region is disposed between the upper surface of the conductive layer and a middle portion of the conductive layer.

11. The semiconductor device of claim 1, wherein an aspect ratio of the opening ranges from about 1:10 to about 1:30.

12. The semiconductor device of claim 1, wherein the conductive layer comprises tungsten (W) or aluminum (Al).

13. A semiconductor device, comprising:
a substrate comprising a conductive region;
a plurality of channel regions extending in a direction substantially perpendicular to an upper surface of the substrate;
a plurality of gate electrodes and a plurality of interlayer insulating layers alternately stacked on the substrate along outer side walls of the plurality of channel regions;
an insulating layer comprising an opening exposing the conductive region and disposed between adjacent channel regions of the plurality of channel regions; and
a common source layer buried within the opening and comprising a first region grown on a lateral surface of the insulating layer and a second region grown on a lateral surface of the first region, wherein the second region is disconnected from the first region.

14. The semiconductor device of claim 13, wherein the conductive region comprises silicide.

15. The semiconductor device of claim 13, wherein the common source layer has a line shape or a pillar shape.

16. A semiconductor device, comprising:
a substrate comprising a conductive region;
an insulating layer disposed on the substrate and comprising an opening exposing the conductive region; and
a conductive layer buried within the opening and comprising a first region disposed on inner side walls of the opening and a second region disposed within the first region,
wherein the first and second regions are separated from each other at a boundary formed between the first and second regions,
wherein lateral surfaces and lower surfaces of the second region are surrounded by the first region.

17. The semiconductor device of claim 16, wherein the second region is disposed in an upper portion of the opening.

18. The semiconductor device of claim 17, wherein a width of the second region increases from an upper surface of the conductive layer toward ends of the lateral surfaces of the second region, and decreases from the ends of the lateral surfaces toward a lowermost point of the second region, wherein the lower surfaces of the second region meet at the lowermost point.

19. The semiconductor device of claim 18, wherein the conductive layer comprises a bowing region formed between the upper surface of the conductive layer and a lower surface of the conductive layer, wherein the conductive layer has a first width at the upper surface of the conductive layer, a second width less than the first width at the lower surface of the conductive layer, and a third width greater than the first width at the bowing region.

20. The semiconductor device of claim 19, wherein the second region extends at least to the bowing region from the upper surface of the conductive layer.
